(19) United States
(12) Patent Application Publication
(10) Pub. No.: US 2011/0209659 A1
(43) Pub. Date: Sep. 1, 2011

(54) CONTROLLING RELATIVE GROWTH RATES OF DIFFERENT EXPOSED CRYSTALLOGRAPHIC FACETS OF A GROUP-III NITRIDE CRYSTAL DURING THE AMMONOTHERMAL GROWTH OF A GROUP-III NITRIDE CRYSTAL

(75) Inventors: Siddha Pimputkar, Goleta, CA (US); Derrick S. Kamber, Goleta, CA (US); James S. Speck, Goleta, CA (US); Shuji Nakamura, Santa Barbara, CA (US)

(73) Assignee: THE REGENTS OF THE UNIVERSITY OF CALIFORNIA, Oakland, CA (US)

(21) Appl. No.: 13/128,105

(22) PCT Filed: Nov. 4, 2009
(86) PCT No.: PCT/US09/63236

§ 371 Date: May 6, 2011

(30) Foreign Application Priority Data
Nov. 7, 2008 (US) 61112545

(51) Int. Cl. C30B 19/10

(52) U.S. Cl. 117/56; 117/206

(57) ABSTRACT

A method for controlling the relative and absolute growth rates of all possible crystallographic planes of a group-III nitride crystal during ammonothermal growth. The growth rates of the various exposed crystallographic planes of the group-III nitride crystal are controlled by modifying the environment and/or conditions within the reactor vessel, which may be subdivided into a plurality of separate zones, wherein each of the zones has their own environment and conditions. The environment includes the amount of atoms, compounds and/or chemical complexes within each of the zones, along with their relative ratios and the relative motion of the atoms, compounds and/or chemical complexes within each of the zones and among the zones. The conditions include the thermodynamic properties each of the zones possess, such as temperatures, pressures and/or densities.

### CROSS REFERENCE TO RELATED APPLICATIONS

This application claims the benefit under 35 U.S.C. Section 119(e) of the following co-pending and commonly-assigned application:

U.S. Provisional Application Ser. No. 61/112,545, filed on Nov. 7, 2008, by Siddha Pimputkar, Derrick S. Kamber, James S. Speck and Shuji Nakamura, entitled “CONTROLLING RELATIVE GROWTH RATES OF DIFFERENT EXPOSED CRYSTALLOGRAPHIC FACETS OF A GROUP-III NITRIDE CRYSTAL DURING THE AMMONOTHERMAL GROWTH OF A GROUP-III NITRIDE CRYSTAL,” attorney's docket number 30794.299-US-P1 (2009-287-1);

which application is incorporated by reference herein.

This application is related to the following co-pending and commonly-assigned U.S. patent applications:

U.S. Utility patent application Ser. No. 11/921,396, filed on Nov. 30, 2007, by Kenji Fujito, Tadao Hashimoto and Shuji Nakamura, entitled “METHOD FOR GROWING GROUP-III NITRIDE CRYSTALS IN SUPERCRITICAL AMMONIA USING AN AUTOCLAVE,” attorneys docket number 30794.129-US-WO (2005-339-2), which application claims the benefit under 35 U.S.C. Section 365(c) of PCT Utility Patent Application Serial No. US2005/024239, filed on Jul. 8, 2005, by Kenji Fujito, Tadao Hashimoto and Shuji Nakamura, entitled “METHOD FOR GROWING GROUP III-NITRIDE CRYSTALS IN SUPERCRITICAL AMMONIA USING AN AUTOCLAVE,” attorneys' docket number 30794.129-WO-01 (2005-339-1);

U.S. Utility patent application Ser. No. 11/784,339, filed on Apr. 6, 2007, by Tadao Hashimoto, Makoto Saito, and Shuji Nakamura, entitled “METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-U1 (2006-204), which application claims the benefit under 35 U.S.C. Section 119(e) of U.S. Provisional Patent Application Ser. No. 60/790,310, filed on Apr. 7, 2006, by Tadao Hashimoto, Makoto Saito, and Shuji Nakamura, entitled “A METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-P1 (2006-204);

U.S. Utility patent application Ser. No. 11/765,629, filed on Jun. 20, 2007, by Tadao Hashimoto, Hitoshi Sato and Shuji Nakamura, entitled “OPTO-ELECTRONIC AND ELECTRONIC DEVICES USING N-FACE OR M-PLANE GaN SUBSTRATE PREPARED WITH AMMONOTHERMAL GROWTH,” attorneys' docket number 30794.184-US-U1 (2006-666), which application claims the benefit under 35 U.S.C. Section 119(e) of U.S. Provisional Application Ser. No. 60/815,507, filed on Jun. 21, 2006, by Tadao Hashimoto, Hitoshi Sato, and Shuji Nakamura, entitled “OPTO-ELECTRONIC AND ELECTRONIC DEVICES USING N-FACE GaN SUBSTRATE PREPARED WITH AMMONOTHERMAL GROWTH,” attorneys' docket number 30794.184-US-P1 (2006-666);

U.S. Utility patent Ser. No. 12/234,244, filed on Sep. 19, 2008, by Tadao Hashimoto and Shuji Nakamura, entitled “GALLIUM NITRIDE BULK CRYSTALS AND THEIR GROWTH METHOD,” attorneys' docket number 30794.244-US-U1 (2007-809), which application claims the benefit under 35 U.S.C. Section 119(e) of U.S. Provisional Patent Application Ser. No. 60/973,662, filed on Sep. 19, 2007, by Tadao Hashimoto and Shuji Nakamura, entitled “GALLIUM NITRIDE BULK CRYSTALS AND THEIR GROWTH METHOD,” attorneys' docket number 30794.244-US-P1 (2007-809-1);

U.S. Utility patent application Ser. No. 11/977,661, filed on Oct. 25, 2007, by Tadao Hashimoto, entitled “METHOD FOR GROWING GROUP III-NITRIDE CRYSTALS IN A MIXTURE OF SUPERCRITICAL AMMONIA AND NITROGEN, AND GROUP III-NITRIDE CRYSTALS GROWN THEREBY,” attorneys' docket number 30794.253-US-U1 (2007-774-2), which application claims the benefit under 35 U.S.C. Section 119(e) of U.S. Provisional Application Ser. No. 60/854,567, filed on Oct. 25, 2006, by Tadao Hashimoto, entitled “METHOD FOR GROWING GROUP-III NITRIDE CRYSTALS IN MIXTURE OF SUPERCRITICAL AMMONIA AND NITROGEN AND GROUP-III NITRIDE CRYSTALS,” attorneys' docket number 30794.253-US-P1 (2007-774);

U.S. Utility patent application Ser. No. ______, filed on same date herewith, by Siddha Pimputkar, Derrick S. Kamber, Makoto Saito, Steven P. DenBaars, James S. Speck and Shuji Nakamura, entitled “GROUP-III NITRIDE MONOCRYSTAL WITH IMPROVED CRYSTAL QUALITY GROWN ON AN ETCHED-BACK SEED CRYSTAL AND METHOD OF PRODUCING THE SAME,” attorneys' docket number 30794.288-US-U1 (2009-154-2), which application claims the benefit under 35 U.S.C. Section 119(e) of U.S. Provisional Application Ser. No. 61/111,644, filed on Nov. 5, 2008, by Siddha Pimputkar, Derrick S. Kamber, Makoto Saito, Steven P. DenBaars, James S. Speck and Shuji Nakamura, entitled “GROUP-III NITRIDE MONOCRYSTAL WITH IMPROVED CRYSTAL QUALITY GROWN ON AN ETCHED-BACK SEED CRYSTAL AND METHOD OF PRODUCING THE SAME,” attorney's docket number 30794.288-US-P1 (2009-154-1);

P.C.T. International Patent Application Serial No. PCT/US09/______, filed on same date herewith, by Derrick S. Kamber, Siddha Pimputkar, Makoto Saito, Steven P. DenBaars, James S. Speck and Shuji Nakamura, entitled “GROUP-III NITRIDE MONOCRYSTAL WITH IMPROVED PURITY AND METHOD OF PRODUCING THE SAME,” attorneys' docket number 30794.295-WO-U1 (2009-282-2), which application claims the benefit under 35 U.S.C. Section 119(e) of U.S. Provisional Application Ser. No. 61/112,555, filed on Nov. 7, 2008, by Derrick S. Kamber, Siddha Pimputkar, Makoto Saito, Steven P. DenBaars, James S. Speck and Shuji Nakamura, entitled “GROUP-III NITRIDE MONOCRYSTAL WITH IMPROVED PURITY AND METHOD OF PRODUCING THE SAME,” attorney's docket number 30794.295-US-P1 (2009-282-1);

P.C.T. International Patent Application Serial No. PCT/US09/______, filed on same date herewith, by Siddha Pimputkar, Derrick S. Kamber, James S. Speck and Shuji Nakamura, entitled “REACTOR DESIGNS FOR USE IN AMMONOTHERMAL GROWTH OF GROUP-III NITRIDE CRYSTALS,” attorneys' docket number 30794.296-WO-U1 (2009-283/285-2), which application claims the benefit under 35 U.S.C. Section 119(e) of U.S. Provisional Application Ser. No. 61/112,560, filed on Nov. 7, 2008, by Siddha Pimputkar, Derrick S. Kamber, James S. Speck and Shuji Nakamura, entitled “REACTOR DESIGNS FOR USE IN AMMONOTHERMAL GROWTH OF GROUP-III NITRIDE CRYSTALS,” attorney's docket number 30794.296-US-P1 (2009-283/285-1);

P.C.T. International Patent Application Serial No. PCT/US09/______, filed on same date herewith, by Siddha Pimputkar, Derrick S. Kamber, James S. Speck and Shuji Nakamura, entitled “NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS,” attorneys' docket number 30794.297-WO-U1 (2009-284-2), which application claims the benefit under 35 U.S.C. Section 119(e) of U.S. Provisional Application Ser. No. 61/112,552, filed on Nov. 7, 2008, by Siddha Pimputkar, Derrick S. Kamber, James S. Speck and Shuji Nakamura, entitled “NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS,” attorney's docket number 30794.297-US-P1 (2009-284-1);

P.C.T. International Patent Application Serial No. PCT/US09/______, filed on same date herewith, by Siddha Pimputkar, Derrick S. Kamber, James S. Speck and Shuji Nakamura, entitled “ADDITION OF HYDROGEN AND/OR NITROGEN CONTAINING COMPOUNDS TO THE NITROGEN-CONTAINING SOLVENT USED DURING THE AMMONOTHERMAL GROWTH OF GROUP-III NITRIDE CRYSTALS,” attorneys' docket number 30794.298-WO-U1 (2009-286-2), which application claims the benefit under 35 U.S.C. Section 119(e) of U.S. Provisional Application Ser. No. 61/112,558, filed on Nov. 7, 2008, by Siddha Pimputkar, Derrick S. Kamber, James S. Speck and Shuji Nakamura, entitled “ADDITION OF HYDROGEN AND/OR NITROGEN CONTAINING COMPOUNDS TO THE NITROGEN-CONTAINING SOLVENT USED DURING THE AMMONOTHERMAL GROWTH OF GROUP-III NITRIDE CRYSTALS TO OFFSET THE DECOMPOSITION OF THE NITROGEN-CONTAINING SOLVENT AND/OR MASS LOSS DUE TO DIFFUSION OF HYDROGEN OUT OF THE CLOSED VESSEL,” attorney's docket number 30794.298-US-P1 (2009-286-1); and

P.C.T. International Patent Application Serial No. PCT/US09/______, filed on same date herewith, by Siddha Pimputkar, Derrick S. Kamber, James S. Speck and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorneys' docket number 30794.300-WO-U1 (2009-288-2), which application claims the benefit under 35 U.S.C. Section 119(e) of U.S. Provisional Application Ser. No. 61/112,550, filed on Nov. 7, 2008, by Siddha Pimputkar, Derrick S. Kamber, James S. Speck and Shuji Nakamura, entitled “USING BORON-CONTAINING COMPOUNDS, GASSES AND FLUIDS DURING AMMONOTHERMAL GROWTH OF GROUP-III NITRIDE CRYSTALS,” attorney's docket number 30794.300-US-P1 (2009-288-1); all of which applications are incorporated by reference herein.

### BACKGROUND OF THE INVENTION

1. Field of the Invention

This invention relates to ammonothermal growth of group-III nitrides.

2. Description of the Related Art

Ammonothermal growth of group-III nitrides, for example, GaN, involves placing, within a reactor vessel, group-III-containing source materials, group-III nitride seed crystals, and a nitrogen-containing solvent, such as ammonia, sealing the vessel and heating the vessel to conditions such that the vessel is at elevated temperatures (between 23° C. and 1000° C.) and high pressures (between 1 atm and, for example, 30,000 atm). Under these temperatures and pressures, the nitrogen-containing solvent becomes a supercritical fluid and normally exhibits enhanced solubility of the group-III-containing source materials into solution. The solubility of the group-III-containing source materials into the nitrogen-containing solvent is dependent on the temperature, pressure and density of the solvent, among other things. By creating two different zones within the vessel, it is possible to establish a solubility gradient where, in one zone, the solubility will be higher than in a second zone. The group-III-containing source materials are then preferentially placed in the higher solubility zone and the seed crystals in the lower solubility zone. By establishing fluid motion of the solvent with the dissolved source materials between these two zones, for example, by making use of natural convection, it is possible to transport the fluid from the higher solubility zone to the lower solubility zone where the group-III nitride crystals are grown on the seed crystals.

The growth rate of the various exposed crystallographic planes of the group-III nitride crystals varies due to the varying number of exposed free electrons for bonding and different surface densities of the different atoms along with varying ratios of the two atoms (group-III and N atoms). It is clearly established that certain crystallographic planes grow faster than others in certain environments and conditions. For example, it has been observed in GaN that among the slow growing, and therefore stable, planes are the c-plane (000-1) and m-planes {10-10} as expressed in Miller-Bravais indices. If the relative growth rate of the m-planes is larger than that of the c-planes, then the resulting crystal may assume a flat puck like shape, having a large c-plane facet and smaller m-plane facets.

For various reasons, it may be beneficial for electronic and optoelectronic devices to be grown on non-polar planes, for example, m-plane {10-10} or a-plane {11-20}, or semi-polar planes, for example, {11-22}, {10-11} or {10-12}, of the group-III nitride crystal. There is therefore a strong desire to make substrates exposing these non-polar or semi-polar surfaces. In order to do this, a large group-III nitride crystal is needed which has a large geometrical cross-section along those planes. If the ammonothermal method is used to make crystals that will subsequently be used as epitaxial substrates, it is important to preferentially grow faster along the c-plane directions ([0001] and [000-1]) than the m-plane and a-plane directions. This assumes, however, that growth along the m-plane and a-plane directions has been large enough to produce substrates with adequate area in the non-polar and semi-polar planes.

Thus, there is a need in the art for methods of controlling the relative and absolute growth rates of all possible crystallographic planes of a group-III nitride crystal during the ammonothermal growth of the crystal. The present invention satisfies this need.

### SUMMARY OF THE INVENTION

To overcome the limitations in the prior art described above, and to overcome other limitations that will become apparent upon reading and understanding the present invention, the present invention discloses a method for controlling relative and absolute growth rates of all possible crystallographic planes of a group-III nitride crystal during ammonothermal growth. The growth rates of the various exposed crystallographic planes of the group-III nitride crystal are controlled by modifying the environment and/or conditions within the reactor vessel, which may be subdivided into a plurality of separate zones, wherein each of the zones has their own environment and conditions. The environment includes the amount of atoms, compounds and/or chemical complexes within each of the zones, along with their relative ratios and the relative motion of the atoms, compounds and/or chemical complexes within each of the zones and among the zones. The conditions include the thermodynamic properties each of the zones possess, such as temperatures, pressures and/or densities.

### BRIEF DESCRIPTION OF THE DRAWINGS

Referring now to the drawings in which like reference numbers represent corresponding parts throughout:

FIG. 1 is a schematic of a high-pressure vessel according to an embodiment of the present invention.

FIG. 2 is a flowchart illustrating the method according to an embodiment of the present invention.

### DETAILED DESCRIPTION OF THE INVENTION

In the following description of the preferred embodiment, reference is made to a specific embodiment in which the invention may be practiced. It is to be understood that other embodiments may be utilized and structural changes may be made without departing from the scope of the present invention.

Apparatus Description

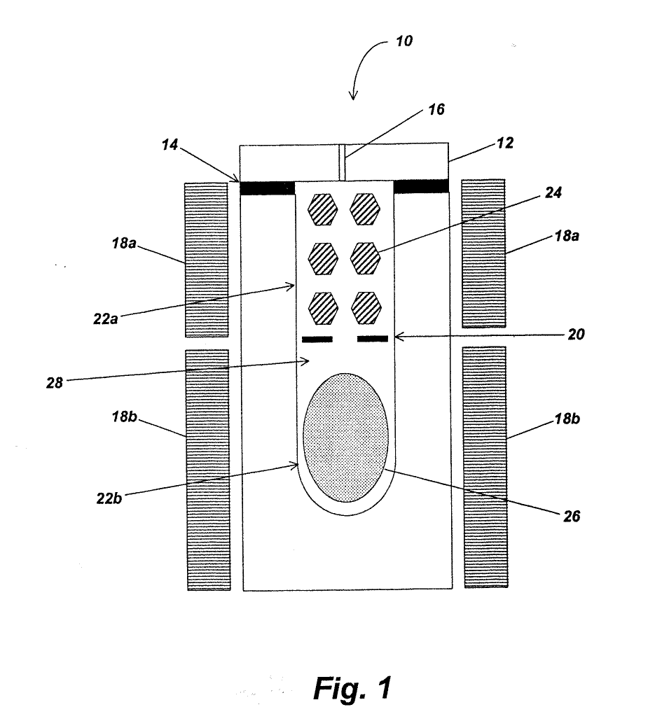

FIG. 1 is a schematic of an ammonothermal growth system comprising a high-pressure reaction vessel 10 according to one embodiment of the present invention. The vessel, which is an autoclave, may include a lid 12, gasket 14, inlet and outlet port 16, and external heaters/coolers 18a and 18b. A baffle plate 20 divides the interior of the vessel 10 into two zones 22a and 22b, wherein the zones 22a and 22b are separately heated and/or cooled by the external heaters/coolers 18a and 18b, respectively. An upper zone 22a may contain one or more group-III nitride seed crystals 24 and a lower zone 22b may contain one or more group-III-containing source materials 26, although these positions may be reversed in other embodiments. Both the group-III nitride seed crystals 24 and group-III-containing source materials 26 may be contained within baskets or other containment devices, which are typically comprised of an Ni—Cr alloy. The vessel 10 and lid 12, as well as other components, may also be made of a Ni—Cr based alloy. Finally, the interior of the vessel 10 is filled with a nitrogen-containing solvent 28 to accomplish the ammonothermal growth.

Process Description

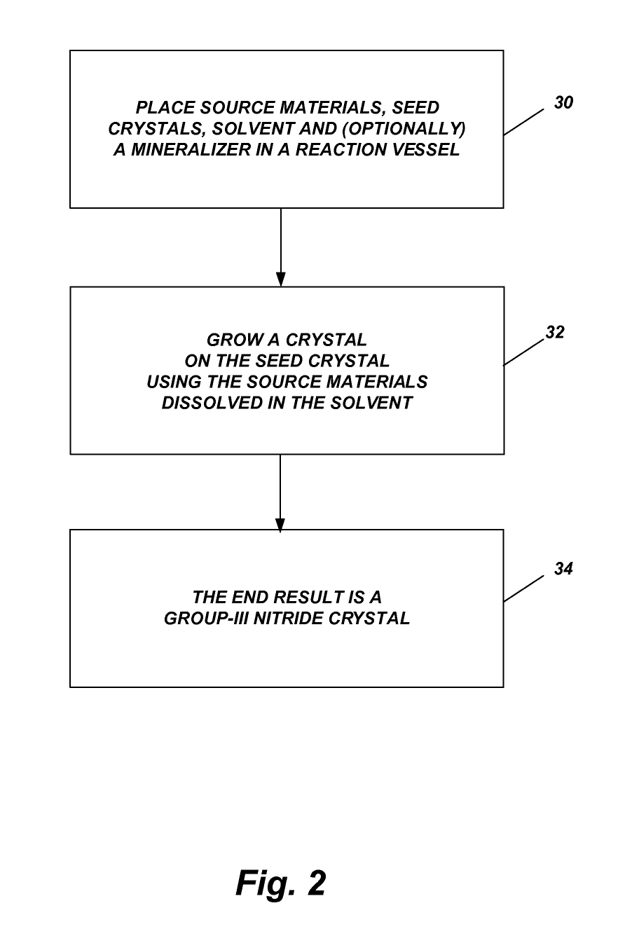

FIG. 2 is a flow chart illustrating a method for obtaining or growing a group-III-nitride-containing crystal using the apparatus of FIG. 1 according to one embodiment of the present invention.

Block 30 represents placing one or more group-III nitride seed crystals 24, one or more group-III-containing source materials 26, and a nitrogen-containing solvent 28 in the vessel 10, wherein the seed crystals 24 are placed in a seed crystals zone (i.e., either 22a or 22b, namely opposite the zone 22b or 22a containing the source materials 26), the source materials 26 are placed in a source materials zone (i.e., either 22b or 22a, namely opposite the zone 22a or 22b containing the seed crystals 24). The seed crystals 24 may comprise a group-III-containing crystal; the source materials 26 may comprise a group-III-containing compound, a group-III element in its pure elemental form, or a mixture thereof, i.e., a group-III-nitride monocrystal, a group-III-nitride polycrystal, a group-III-nitride powder, group-III-nitride granules, or other group-III-containing compound; and the solvent 28 may comprise supercritical ammonia or one or more of its derivatives. An optional mineralizer may be placed in the vessel 10 as well, wherein the mineralizer increases the solubility of the source materials 26 in the solvent 28 as compared to the solvent 28 without the mineralizer.

Block 32 represents growing group-III nitride crystals on one or more surfaces of the seed crystal 24, wherein the environments and/or conditions for growth include forming a temperature gradient between the seed crystals 24 and the source materials 26 that causes a higher solubility of the source materials 26 in the source materials zone and a lower solubility, as compared to the higher solubility, of the source materials 26 in the seed crystals zone. Specifically, growing group-III nitride crystals on one or more surfaces of the seed crystal 24 occurs by changing the source materials zone temperatures and the seed crystals zone temperatures to create a temperature gradient between the source materials zone and the seed crystals zone that produces a higher solubility of the source materials 26 in the solvent 28 in the source materials zone as compared to the seed crystals zone. For example, the source materials zone and seed crystals zone temperatures may range between 0° C. and 1000° C., and the temperature gradients may range between 0° C. and 1000° C.

Block 34 comprises the resulting product created by the process, namely, a group-III-nitride crystal grown by the method described above. A group-III-nitride substrate may be created from the group-III-nitride crystal, and a device may be created using the group-III-nitride substrate.

Controlling Relative and Absolute Growth Rates

The present invention envisions controlling the relative and absolute growth rates of all possible crystallographic planes of a group-III nitride crystal 34 during the ammonothermal growth of the crystal 34. Specifically, the growth rates of the various exposed crystallographic planes of the group-III nitride crystal 34 may be controlled by modifying the environment and/or conditions within the vessel 10 of FIG. 1 during the process steps of FIG. 2, wherein the vessel 10 may be subdivided into a plurality of separate zones 22a and 22b, each of these zone 22a and 22b having their own environment and/or conditions.

In this context, the terms environment and conditions should be considered rather loosely. For example, the environment may be interpreted as describing, among other things, the amount of atoms, compounds and/or complexes within the zones 22a and 22b along with their relative ratios, and the relative motion of the atoms, compounds and/or complexes within each of the zones 22a or 22b, and among the zones 22a and 22b. In another example, the conditions may be interpreted as describing, among other things, the thermodynamic properties of the zones 22a and 22b, such as, but not limited to, temperatures, pressures and/or densities of the zones 22a and 22b.

The environments and/or conditions within the vessel 10 that may be modified are numerous. The following list, which is by no means complete and should not be considered an exclusive list, describes possible methods that may be used to modify the environments and/or conditions. These methods may be used either singly or in combination to achieve the desired effects.

Ratio of Group-III to Group-V Elements within the Solvent

By varying the ratio of group-III elements to group-V elements making up the solvent 28, it may be possible to control the growth rate of the different crystallographic planes of the group-III nitride crystal 34. In order to achieve this desired ratio of group-III to group-V elements, it is possible, for example, to mix one or more nitrogen-containing fluids with one or more boron-containing fluids, and bring the resultant mixture into a gas and/or supercritical state, in which state it may act as the solvent 28 and transport medium of the source materials 26 for the ammonothermal growth of the group-III nitride crystal 34 on the seed crystals 24. The nitrogen-containing and boron-containing fluid may be composed of any possible combination and any possible ratio of nitrogen-containing, boron-containing, and/or boron-containing and nitrogen-containing compounds such as, but limited to, borane (BH₃), diborane (B₂H₆), borazane (BNH₆), borazine (B₃N₃H₆), ammonia (NH₃), hydrazine (N₂H₄), triazane (N₃H₅), tetrazane (N₄H₆), triazene (N₃H₃), diimine (N₂H₂), nitrogen (N₂) and nitrene (NH).

The ratio of group-III to group-V elements present during growth may further be set initially prior to growth, but may also be varied by the addition of or removal of material during, in-between or after the various steps involved in growing the group-III nitride crystal 34 using the ammonothermal method. For example, it might be possible during growth to add to the already existing solvent 28 within the vessel 10 additional diborane in form of a gaseous fluid and therefore increase the group-III to group-V ratio within the solvent 28. This may be achieved, for example, by lowering the pressure within the vessel 10 to a level that is below the available supply pressure of the gaseous diborane gas (this may be achieved by lowering the average temperature of the vessel 10) and opening the inlet and outlet port 16 to supply the vessel 10 with a predetermined amount of gas. After adding the desired quantity of diborane gas, the port 16 is closed and the temperature may be raised to the desired levels and/or to levels that would obtain the desired pressures within the vessel 10.

Additionally, it may be desirable to have the vessel 10 at a certain pressure and temperature, but the concentration of the nitrogen-containing and/or boron-containing compounds at certain concentrations within the vessel 10. Since the three parameters of (1) pressure, (2) temperature and (3) density are interrelated, it may be necessary to add additional material to the vessel 10 to obtain the desired pressure at the given temperature. Therefore, this invention also envisions the possibility of adding additional, non-nitrogen-containing and/or non-boron-containing compounds, such as, but not limited to, hydrogen (H₂), helium (He), neon (Ne), argon (Ar), krypton (Kr), xenon (Xe), radon (Rn), fluorine (F₂), chlorine (Cl₂), bromine (Br₂), iodine (I₂), and/or astatine (At₂) to the vessel 10.

Temperature Gradients within the Vessel During Growth

It may further be possible to control the relative and/or absolute growth rates of the various crystallographic planes of the group-III nitride crystal 34 by varying the temperature gradients within the vessel 10. These gradients may be made across multiple zones 22a and 22b, namely, the source materials zone and the seed crystals zone, and/or alternatively across any single zone 22a or 22b, namely, the source materials zone or the seed crystals zone. The effect of creating one or more temperature gradients may result in different kinetics and equilibrium thermodynamics to be present near and/or at the surface altering the rate of absorption of group-III and/or group-V elements, hence modifying the absolute and relative growth rates of the different crystallographic planes of the group-III nitride crystal 34. The temperature gradients may further be varied during and/or in-between steps 30 and 32 in the process of growing the group-III nitride crystal 34 shown in FIG. 2.

Addition of Mineralizers, Gases, Materials to the Solvent

It may further be possible to control the relative and/or absolute growth rates of the various crystallographic planes of the group-III nitride crystal 34 by additionally adding one or more mineralizers and/or gases of any phase, form or composition. One example of such an addition of material would be the addition of sodium (Na). By adding sodium, it may act as a mineralizer and hence decrease the ratio of the solvent 28, which may have its own group-III to group-V material ratio, to group-III material dissolved in solution. Depending on the ratio of available group-III elements in solution intended to be incorporated into the group-III nitride crystal 34 to the available nitrogen (N) material available for incorporation, the arrival rate of the elements to/on the surface may vary and therefore the growth rates may vary.

Further by the addition of other material(s) and/or compound(s) and/or complex(es), it may be possible to change the chemistry near/at the surface and/or the physics involved in the uptake of material into of the group-III nitride crystals 34. The effect of this may be manifold, but may effect the rate of absorption of material to the surface and/or may change the relevant chemical and/or physical processes involved in the growth of the group-III nitride crystal 34, further enhancing and/or modifying the relative and absolute growth rates. One example of how the addition of mineralizers and/or other gases and/or material may be beneficial to growth, may be that the material that is added preferentially acts as a surfactant on the group-III nitride crystal 34, possibly enhancing and/or modifying growth rates of the various crystallographic planes. A surfactant may be described as a material which preferentially attaches itself to most, if not all, of the surface(s) of the crystal 34, thereby possibly modifying the various chemical and/or physical properties of the surface, but still remains permeable for the various group-III and group-V material which may diffuse through it to the underlying group-III nitride crystal 34. Further, through the addition of one or more surfactant(s) to the seed crystals 24, it may be possible to reduce impurity incorporation into the group-III nitride crystal 34.

Velocity of Solvent Motion Relative to the Crystal's Surface

By varying the velocity of the solvent 28 motion, it may be possible to control the relative and absolute growth rates of the various crystallographic planes of the group-III nitride crystal 34. The importance of the direction and/or speed of the fluid motion is that both the rate at which material may be absorbed at the surface and/or the local concentration of group-III and/or group-V material may be different. Hence, by either increasing or decreasing the solvent 28 velocity, the local concentration of group-III and/or group-V material may vary due to either a faster or slower replenishing rate of the absorbed material and/or absorption rate of the material onto the surface of the group-III nitride crystal 34. The relative direction of solvent 28 motion with respect to the crystallographic planes of the group-III nitride crystal 34 is also important as depending on the angle of the velocity of the solvent 28 makes with the surface, the physical and/or chemical processes at the surface involved in absorbing material onto the crystal 34 may be varied, along with the local concentration of material, further changing the growth rates.

Ratio of Group-III Containing Source Materials to Solvent

It may further be possible to control the relative and/or absolute growth rates of the various crystallographic planes of the group-III nitride crystal 34 by controlling the ratio of group-III containing source materials 26 to solvent 28 ratio. By varying this ratio, it may be possible to control the amount of source materials 26 in the solvent 28 during the growth of the group-III nitride crystal 34 and hence vary the arrival rate of the source materials onto the surface of the group-III nitride crystal 34. The amount of surface area of the source materials 26 may also be an important property for this control mechanism. This ratio may further be controlled through the addition of specific mineralizers, as discussed previously.

Absolute and Partial Pressures within the Vessel

It may further be possible to control the relative and/or absolute growth rates of the various crystallographic planes of the group-III nitride crystal 34 by controlling the absolute and/or partial pressure of the different atoms and/or compounds within the vessel 10. This may be achieved by changing the concentration(s) of the various compounds and/or atoms comprising the solvent 28. This may include, but is not limited to, adding additional borane (BH₃), diborane (B₂H₆), borazane (BNH₆), borazine (B₃N₃H₆), ammonia (NH₃), hydrazine (N₂H₄), triazane (N₃H₅), tetrazane (N₄H₆), triazene (N₃H₃), diimine (N₂H₂), nitrogen (N₂), nitrene (NH) and/or hydrogen (H₂) to the mixture.

Additionally, if it is desirable to increase the total pressure within the vessel 10 without changing the concentrations of the material(s) making up the solvent 28, this may be done by adding atoms and/or compounds to the vessel 10 which are not primary constituents of the solvent 28. Examples of gases that may be used and may remain relatively inert in the vessel 10 include, but are not limited to, helium (He), neon (Ne), argon (Ar), krypton (Kr), xenon (Xe), radon (Rn), fluorine (F₂), chlorine (Cl₂), bromine (Br₂), iodine (I₂), and/or astatine (At₂).

The effect of changing the partial pressure and total system pressure of the vessel 10 may change the rate at which group-III and/or group-V containing materials arrive at the surface of the group-III nitride crystal 34 and incorporate themselves thereon. Depending on the rate at which the group-III and/or group-V containing materials arrive at the surface of the group-III nitride crystal 34 and depending on the particular structure of the group-III and/or group-V containing compounds as they arrive at the surface of the group-III nitride crystal 34, certain crystallographic planes of the group-III nitride crystal 34 may be favored for growth, due to the prevailing chemical and/or physical processes involved at the surface for that particular crystallographic plane of the group-III nitride crystal 34. The prevailing chemical and/or physical processes involved at the surface of the group-III nitride crystal 34 may be a function of the particular crystallographic plane, due to the varying nature of the exposed atoms (group-III and nitrogen) and the resulting electron configuration at the surface, along with the spatial separation between the various atoms/electron orbitals at the surface.

Further, by changing the total system pressure, it may be possible to change the kinetics of the reactions involved in the growth process, further modifying the growth rates.

Summary

In conclusion, control over which facet of the group-III nitride crystal 34 is exposed during growth and the relative growth rates of the exposed surfaces of the group-III nitride crystal 34 is of great importance as it may, for example, also lead to the control of impurity and doping incorporation into the group-III nitride crystal 34 along with improved crystal 34 quality, which has been shown to be dependent on which plane is exposed during growth, among other things.

With regard to future work, experimental tests need to be performed to determine functional dependence of the ratio of group-III elements to group-V elements to the relative growth rates of the different exposed crystallographic planes. Additional steps also include optimizing the parameters to give an optimal result and then incorporate scaling of this technology to larger reactor designs.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for growing crystals, comprising:
(a) placing source materials and seed crystals into a vessel;
(b) filling the vessel with a solvent for dissolving the source materials and transporting a fluid comprised of the solvent with the dissolved source materials to the seed crystals for growth of the crystals; and
(c) controlling relative and absolute growth rates of crystallographic planes of the crystal during growth, by modifying an environment and conditions within the vessel.

2. The method of claim 1, wherein the source materials comprise group-III-containing source materials, the seed crystals comprise group-III nitride seed crystals, the solvent comprises a nitrogen-containing solvent, and the crystals comprise group-III nitride crystals.

3. The method of claim 2, wherein the vessel is subdivided into a plurality of zones, and each of the zones has their own environment and conditions.

4. The method of claim 3, wherein the environment comprises an amount of atoms, compounds or complexes within each of the zones along with their relative ratios and a relative motion of the atoms, compounds or complexes within each of the zones and among the zones.

5. The method of claim 4, wherein the environment comprises a ratio of group-III to group-V elements.

6. The method of claim 4, wherein the environment comprises an addition of mineralizers, gases and materials to the solvent.

7. The method of claim 4, wherein the environment comprises a speed and direction of the solvent's motion relative to the crystal's surface.

8. The method of claim 3, wherein the environment comprises a ratio of source materials to the solvent.

9. The method of claim 3, wherein the environment is modified by adding materials to the vessel or removing materials from the vessel.

10. The method of claim 3, where the conditions include thermodynamic properties of materials in the zones, such as temperatures, pressures or densities.

11. The method of claim 3, where the conditions include one or more temperature gradients within the vessel.

12. The method of claim 3, where the conditions include absolute and partial pressures within the vessel.

13. An apparatus for growing crystals, comprising:
(a) a vessel for containing source materials and seed crystals,
(b) wherein the vessel is filled with a solvent for dissolving the source materials and a fluid comprised of the solvent with the dissolved source materials is transported to the seed crystals for growth of the crystals; and
(c) wherein relative and absolute growth rates of crystallographic planes of the crystal are controlled during growth, by modifying an environment and conditions within the vessel.

14. The apparatus of claim 13, wherein the source materials comprise group-III-containing source materials, the seed crystals comprise group-III nitride seed crystals, the solvent comprises a nitrogen-containing solvent, and the crystals comprise group-III nitride crystals.

15. The apparatus of claim 14, wherein the vessel is subdivided into a plurality of zones, and each of the zones has their own environment and conditions.

16. The apparatus of claim 15, wherein the environment comprises an amount of atoms, compounds or complexes within each of the zones along with their relative ratios and a relative motion of the atoms, compounds or complexes within each of the zones and among the zones.

17. The apparatus of claim 16, wherein the environment comprises a ratio of group-III to group-V elements.

18. The apparatus of claim 16, wherein the environment comprises an addition of mineralizers, gases and materials to the solvent.

19. The apparatus of claim 16, wherein the environment comprises a speed and direction of the solvent's motion relative to the crystal's surface.

20. The apparatus of claim 15, wherein the environment comprises a ratio of source materials to the solvent.

21. The apparatus of claim 15, wherein the environment is modified by adding materials to the vessel or removing materials from the vessel.

22. The apparatus of claim 15, where the conditions include thermodynamic properties of materials in the zones, such as temperatures, pressures or densities.

23. The apparatus of claim 15, where the conditions include one or more temperature gradients within the vessel.

24. The apparatus of claim 15, where the conditions include absolute and partial pressures within the vessel.
